(19) United States
(12) Patent Application Publication
(10) Pub. No.: US 2005/0189610 A1
(43) Pub. Date: Sep. 1, 2005

(54) Semiconductor device and method of manufacturing the same

(76) Inventors: Koji Usuda, Yokohama-shi (JP); Shinichi Takagi, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/064,001

(22) Filed: Feb. 24, 2005

(30) Foreign Application Priority Data
Feb. 27, 2004 (JP) 2004-053395

(51) Int. Cl. H01L 31/0328

(52) U.S. Cl. 257/510

(57) ABSTRACT

A method of manufacturing a semiconductor device, includes selectively forming a mask having an opening on a semiconductor substrate, ion-implanting oxygen to a predetermined depth position of the substrate from a surface of the substrate exposed in the opening of the mask, carrying out annealing with respect to the substrate to oxidize an ion implantation region so that an insulating layer is formed, and forming a first semiconductor element on a region of the semiconductor substrate on the insulating layer, and forming a second semiconductor element on a region other than the region formed with the insulating layer.

### CROSS-REFERENCE TO RELATED APPLICATIONS

This application is based upon and claims the benefit of priority from prior Japanese Patent Application No. 2004-053395, filed Feb. 27, 2004, the entire contents of which are incorporated herein by reference.

### BACKGROUND OF THE INVENTION

1. Field of the Invention

The present invention relates to a semiconductor device having a structure in which part of a semiconductor substrate is isolated via an insulating layer. Moreover, the present invention relates to a method of manufacturing the semiconductor device.

2. Description of the Related Art

The performance of semiconductor elements used in Si-LSIs, in particular, MOSFETs has been enhanced year by year with advances in LSI technology. However, a limit to the lithography technique is indicated in light of recent process techniques, while saturation of mobility is indicated in light of element physics. For this reason, it is very difficult to achieve high performance of the semiconductor elements.

The following technique has attracted special interest as a method of improving electron mobility, which is one of the high-performance indices of an Si-MOSFET. According to the technique, strain is applied to an active layer for forming elements. The strain is applied to the active layer, and thereby, the band structure changes and carriers contained in a channel are prevented from scattering. Thus, it is expected to enhance the mobility. More specifically, a compound crystal layer consisting of a material having a lattice constant larger than silicon (Si) is formed on an Si substrate. For example, a strain-relaxed SiGe compound crystal layer (hereinafter, referred simply to as SiGe layer) having 20% Ge concentration is formed on the Si substrate. When an Si layer is formed on the SiGe layer, a strained Si layer to which strain is applied is formed according to the difference in the lattice constant. The following report has been made (e.g., see J. Welser, J. L. Hoyt, S. Takagi and J. F. Gibbons, IEDM 94-373). According to the report, when the strained Si layer is used as a channel of the semiconductor device, it is possible to obtain electron mobility of about 1.76 times as much as the case where a non strained Si channel is used.

In order to form the foregoing strained Si channel on an silicon-on-insulator (SOI) structure, the present inventors realized a device structure using the following method. According to the method, the strained Si layer is formed on the strain-relaxed SiGe layer on a buried oxide layer (e.g., see T. Mizuno et al., 11-3, 2002 Symposia on VLSI Tech.). A transistor having such a structure is excellent in short channel effect (SCE) and reduction of parasitic capacitance; therefore, it serves to realize high-performance elements.

However, if the scale-down further advances, for example, a 35 nm node element will be produced in future. In this case, the thickness of the strained Si channel is experimentally ⅓ to ¼ of the gate length, that is, several nanometers, and thus, becomes extremely thin. For this reason, there is a possibility that the crystal layer deteriorates. For example, if the strained Si layer is given as one example, the lattice spacing between a front-end layer and a back-end strain-applied layer is percent (%) order to apply strain. As a result, crystal defect resulting from strain occurs in crystal.

If the strained Si channel contacts with a semiconductor material different from Si, for example, front-end SiGe layer, there is a possibility that Ge diffuses from the SiGe layer to the strained Si layer. This is a factor of causing a strain change, carrier transportation change or increase of interface state in the element producing process and in the device operation. For this reason, there is a possibility that element characteristics are degraded.

Meanwhile, one-chip technique development, typical of DRAM embedded process, is important as a technique required for manufacturing logic operation elements applied to a next generation computer system. The foregoing embedded process has attracted special interest for the following reason. Because, the embedded process is a technique of forming a logic circuit and a memory elements such as DRAM on the same substrate, and reducing power consumption and cost while maintaining high speed operation. In this case, high performance elements having high processing speed are required as the logic circuit. On the other hand, high-quality semiconductor devices must be manufactured in view of yield to form the memory elements.

In the technique of integrating high-performance logic element and high-quality memory element on the same substrate, it is necessary to break down a limit of high-performance logic element resulting from a limit of scale-down. In addition, there is a limit in the method of integrating high-quality memory elements on the single substrate like the conventional technique. Moreover, the following various problems are mixed; as a result, there is a problem that it is more and more difficult to achieve integration between generations. The various problems are as follows.
Reduction of element performance enhancement effect resulting from the advance of scale-down
Cost increase
Increase of the number of manufacturing processes
Difficulty of circuit design by drive force reduction resulting from high integration

Consequently, it is necessary to realize the technique of integrating logic elements requiring higher performance and memory elements requiring higher quality and higher integration on the same substrate. It has been desired to realize a semiconductor device which is adaptable to reduction of cost and number of processes, and to realize a method of manufacturing the semiconductor device.

### BRIEF SUMMARY OF THE INVENTION

According to a first aspect of the invention, there is provided a method of manufacturing a semiconductor device which comprises:
selectively forming a mask having an opening on a semiconductor substrate;
ion-implanting oxygen to a predetermined depth position of the substrate from a surface of the substrate exposed in the opening of the mask;
carrying out annealing with respect to the substrate to oxidize an ion implantation region so that an insulating layer is formed; and
forming a first semiconductor element on a region of the semiconductor substrate on the insulating layer, and forming a second semiconductor element on a region other than the region formed with the insulating layer.

According to a second aspect of the invention, there is provided a semiconductor device, which comprises:
a semiconductor substrate;
a first insulating film partially formed at a predetermined depth position from a surface of the semiconductor substrate;
a second insulating film formed extending from at least part of the first insulating film to the surface of the semiconductor substrate, a thickness of the second insulating film in a direction parallel to the surface of the second insulating being 40 to 150 nm;
a first semiconductor element formed on a first region of the semiconductor substrate above the first insulating film; and
a second semiconductor element formed on a second region of the semiconductor substrate other than the first region formed with the first insulating film.

According to a third aspect of the invention, there is provided a semiconductor device, which comprises:
a semiconductor substrate;
a first insulating film partially formed at a predetermined depth position from a surface of the semiconductor substrate;
a second insulating film formed extending from at least part of the first insulating film to the surface of the semiconductor substrate;
a first semiconductor element formed on a first region of the semiconductor substrate above the first insulating film; and
a second semiconductor element formed on a second region of the semiconductor substrate other than the first region formed with the first insulating film; and
at least one-layer added semiconductor layer formed on at least one of the first semiconductor region and the second semiconductor region, in which at least part of the first semiconductor element or the second semiconductor element is formed.

### BRIEF DESCRIPTION OF THE SEVERAL VIEWS OF THE DRAWING

FIG. 1 is a cross-sectional view showing the element structure of a semiconductor device according to a first embodiment of the present invention;

FIG. 2 is a cross-sectional view showing another element structure of the semiconductor device according to the first embodiment;

FIG. 3 is a cross-sectional view showing still another element structure of the semiconductor device according to the first embodiment;

FIGS. 4A and 4B are cross-sectional views to explain the process of forming the element structure of the semiconductor device according to the first embodiment;

FIG. 5 is a cross-sectional view showing the element structure of a semiconductor device according to a second embodiment of the present invention;

FIG. 6 is a cross-sectional view showing the element structure of a semiconductor device according to a third embodiment of the present invention;

FIG. 7 is a cross-sectional view showing the element structure of a semiconductor device according to a fourth embodiment of the present invention;

FIG. 8 is a cross-sectional view showing the element structure of a semiconductor device according to a fifth embodiment of the present invention;

FIG. 9 is a cross-sectional view showing the element structure of a semiconductor device according to a sixth embodiment of the present invention;

FIG. 10 is a cross-sectional view showing the element structure of a semiconductor device according to a seventh embodiment of the present invention; and

FIG. 11 is a cross-sectional view showing the element structure of the semiconductor device according to a modification of the seventh embodiment.

### DETAILED DESCRIPTION OF THE INVENTION

According to embodiments of the present invention described below, a semiconductor substrate is formed with first and second insulating films. An island-like semiconductor region surrounded by these insulating films is electrically isolated from other semiconductor regions (substrate). In this manner, it is possible to realize partial SOI, and each semiconductor region is formed with a semiconductor layer having different characteristic. For example, it is possible to form a material such as strain Si having high mobility in SOI part only.

In the technique of integrating a high-performance logic element and a high-quality memory element on the same substrate, the logic element is formed in the SOI part while the memory element is formed in the substrate part. In this manner, it is possible to integrate a high-performance logic element and a high-quality and high-integration memory element on the same substrate. Moreover, this serves to reduce the cost and the number of processes.

Preferably, the second insulating film reaches the surface of the substrate from the peripheral portion of the first insulating film. Even if the second insulating film does not reach the substrate surface, it contributes to isolation between island-like semiconductor region and other semiconductor regions.

Embodiments of the present invention will be described below with reference to the accompanying drawings.

### First Embodiment

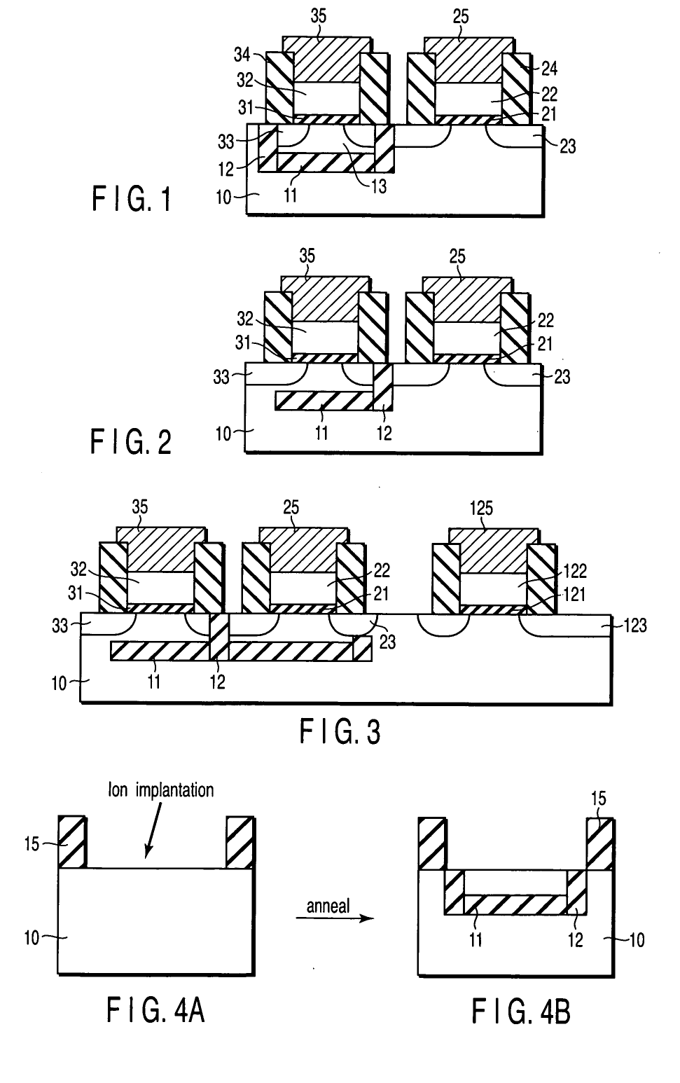

FIG. 1 is a cross-sectional view showing the element structure of a semiconductor device according to a first embodiment of the present invention. Part of a Si substrate 10 (left-side region in FIG. 1) is formed with an insulating layer (first insulating film) 11 such as SiO₂. The insulating layer 11 is formed in parallel with the substrate surface at the depth position of 100 nm from the surface of the substrate 10. An insulating layer (second insulating film) 12 such as SiO₂ is further formed extending from the peripheral portion of the insulating layer 11 to the substrate surface. Preferably, the depth of the insulating layer 11 from the substrate surface is within a range of 50 to 400 nm typically in a range of several nm to 1000 nm. An island-like semiconductor region 13 surrounded by insulating layers 11 and 12 is given as a Si isolation layer, which is electrically isolated from the substrate 10.

In the right-side region on the Si substrate 10, a gate insulating layer 21 is formed on the surface of the substrate 10, and a gate electrode layer 22 is further formed thereon, thereby forming a MOSFET. On the other hand, in the left-side region on the Si substrate 10, a gate insulating layer 31 is formed on the Si isolation layer 31, and a gate electrode layer 32 is further formed thereon, thereby forming a MOSFET. In FIG. 1, reference numerals 23 and 33 denote source/drain regions, 24 and 34 denote interlayer insulating films, 25 and 35 denote interconnect electrodes. The depth of the source/drain regions depends on the applied process technique and is in general under 1000 nm, typically 500 nm and 100 nm. In the high-performance devices in the next generation, the depth will be under 10 nm and may be as thick as the channel region.

In the left-side region of FIG. 1, the MOSFET is formed having a structure close to the SOI structure. According to the conventional SOI structure, the insulating layer is formed parallel to the substrate surface. In contrast, according to the first embodiment, the end portion of the insulating layer is formed toward the substrate surface. More specifically, the structure is provided having two insulating layers described below. One is the insulating layer 11, which is buried in the substrate 10 and formed parallel to the substrate surface. Another is the insulating layer 12, which is formed extending from the peripheral portion of the insulating layer 11 toward the substrate surface. The insulating layer 12 fully connects the insulating layer 11 and the substrate surface, and part of the Si substrate 10 is fully isolated from the substrate via the insulating layers 11 and 12. The structure described above is shown in FIG. 1.

As illustrated in FIG. 2, the insulating layer 12 may be formed extending to the surface side from part of the peripheral portion of the insulating layer 11, and not the entire peripheral portion thereof. In other words, it is unnecessary to fully surround the Si isolation layer with insulating layers 11 and 12 so long as part of the Si isolation layer is surrounded. In this case, the insulating layer 12 may be formed so that it reaches the substrate surface, and so that it does not reach there. In any case, the merits of the conventional SOI element, that is, the interference between two elements as shown in FIG. 2 is reduced, and the effects of eliminating the latch-up effect and parasitic transistor effect are obtained. In addition, if the element is used as a single element, parasitic capacitance and short channel effect (SCE) are reduced. Either of the structure shown in FIG. 1 or FIG. 2 is arbitrarily determined in accordance with the circuit design.

As depicted in FIG. 3, the insulating layer 12 may be formed extending to the surface side from the middle portion of the insulating layer 11, and not the peripheral portion thereof. In addition, the insulating layer 12 may be formed from both part of the peripheral portion and the middle portion. The insulating layer 12 does not necessarily reach the substrate surface, and may be formed partway without reaching the substrate surface.

According to the structure shown in FIG. 3, the insulating layer 12 is formed from the middle of the insulating layer 12 to the substrate surface. A MOSFET is formed right and left of the layer 12, thereby forming a CMOS. The rightmost side of FIG. 3 is further formed with a MOSFET for memory element. In FIG. 3, a reference numeral 121 denotes a gate insulating layer, 122 denotes a gate electrode, 123 denotes a source/drain region, and 125 denotes an interconnect electrode.

FIGS. 4A and 4B are cross-sectional views to explain the process of forming the foregoing insulating layers 11 and 12. As shown in FIGS. 4A and 4B, the surface of the substrate 10 is previously formed with a mask 15 such as oxide film, and thereafter, oxygen is implanted into the substrate 10 using ion implantation. Thereafter, heat treatment is carried out so that insulating layers 11 and 12 are formed at an arbitrary place. The first embodiment differs from the case of carrying out ion implantation and heat treatment with respect to the entire substrate without forming the mask 15, thereby forming a flat insulating film. More specifically, the partially selected mask 15 is used, and thereby, the insulating layer 11 is lifted up to the substrate surface at the opening end of the mask 15, and thus, the insulating layer 12 is formed. Thereafter, the end portion of the insulating layer 12 reaches the substrate surface according to the ion implantation condition. In this manner, the portion surrounded by insulating layers 11 and 12 is isolated from the substrate.

According to the ion implantation condition, acceleration voltage is about 30 to 300 keV, and dose is 1×10¹⁶ to 9×10¹⁸ cm⁻². Typically, the acceleration voltage is 150 to 250 keV, and the dose is 1×10¹⁷ to 1×10¹⁸ cm⁻². Considering the process after that, it is preferable that films such as oxide film and nitride film used for Si process are used as the mask layer 15. The mask layers have a thickness of 10 to 5000 nm, typically, 100 to 3000 nm. The mask layer end shape and the ion implantation condition have a complementary relation; therefore, various combinations may be employed. More specifically, the mask end portion is formed vertically to the substrate surface, and ion is obliquely implanted into the substrate surface.

The process of forming the insulating layers 11 and 12 will be described below in detail. The insulating layers 11 and 12 are formed using the combination of the foregoing oxygen ion implantation and high-temperature annealing after that. Conditions are applied so that a buried oxide (box) layer and silicon-on-insulator (SOI) layer thereon each have good quality. The oxygen ion implantation dose is 3 to 5×10¹⁷ cm⁻² considering the crystallinity of the SOI layer. Usually, the dose is 3.5 to 4.5×10¹⁷ cm⁻² in a normal SOI layer. In order to form SiGe on insulator (SGOI) layer, the dose is set to the same as above or slightly increased, and thereby, a layer having higher crystallinity is obtained. Preferably, the dose is 3.8 to 4.8×10¹⁷ cm⁻². The ion acceleration voltage is 150 to 250 keV.

When the height of the mask is set as H and the width is set as L, an ion implantation angle θ to the substrate surface is smaller than 95 degrees and larger than tan θ=H/L. In order to obtain a structure such that the entire end portion of the box layer extends to the substrate surface, the rotation of the substrate for preventing an influence by the mask is important. It is preferable that the substrate temperature in ion implantation is within a range of room temperature to 900° C.

The high-temperature annealing after that is carried out under the conditions given below. Annealing is carried out at a temperature of 900 to 1400° C., in a nitrogen atmosphere in which oxygen partial pressure is 0.1 to 50% for 2 to 20 hours. In the case of Si, annealing is carried out at a temperature of 1300 to 1370° C. for 4 to 8 hours. Typically, annealing is carried out at a temperature of 1350° C. for 4 to 8 hours. In the case of the SGOI layer, it is necessary to reduce the anneal temperature depending on Ge concentration of the SiGe layer previously formed on the Si layer. If the Ge concentration of the SiGe layer is 50%, annealing at a temperature of 1200° C. or less is required to form an SGOI layer having high crystallinity. In the annealing atmosphere, it is preferable to secure oxygen partial pressure of at least 0.1%.

The thickness of the box layer formed by anneal is typically 100 nm at the middle portion surrounded by the mask. Although it depends on ion dose, it is possible to readily form a box layer having a thickness ranging 40 to 150 nm. The thickness in the horizontal direction of the vertical portion is basically the same as the middle portion, that is, 40 to 150 nm although it relates to the ion implantation angle. The present process depends on the height of the mask layer 15, and the height of the mask layer 15 is typically 1 μm. In this case, the mask 15 may be formed thinner or thicker than 1 μm. If the ion acceleration voltage is higher (200 keV or more), there is a high possibility that ion is implanted via the mask layer; for this reason, proper process conditions should be given.

The substrate after ion implantation is subjected to the heat treatment described above, and thereafter, has the shape shown in FIG. 4B. For example, if the ion implantation condition is 1×10¹⁸ cm⁻² or more, the surface of the portion surrounded by isolated insulating layers 11 and 12 becomes higher than other portions. Considering the process after that, there are the following cases. One is the case where it is preferable that the surface height formed with two elements as shown in FIG. 1 is the same in the right-hand and left-hand sides. Another is the case where it is not essential that the surface height is the same. This is selectively used in accordance with the process.

Even if the surface height is not the same, chemical mechanical polishing (CMP) is carried out later, thereby planarizing the entire surface of the substrate. Moreover, an SOI substrate is prepared using separation by implanted oxygen (SIMOX) and bonding, and the SOI layer other than desired portions and the insulating layer under there are removed. Thereafter, the structure shown in FIG. 1 is obtained via oxidation and re-growth to portions other than the SOI portion.

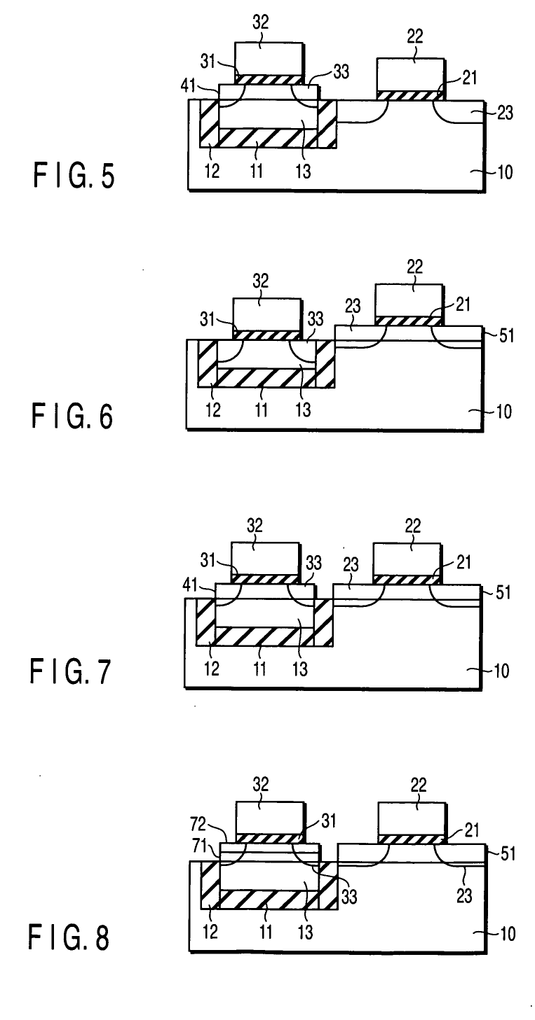

FIG. 5 to FIG. 11 described later each shows a state that part of the substrate is fully isolated via these insulating layers 11 and 12 as shown in FIG. 1. In any case, the end portion of the insulating layer is formed by arbitrary desired height toward the substrate surface, as seen from FIG. 2.

According to the first embodiment, the Si substrate 10 is formed with the insulating layer 11 in parallel with the substrate surface. The insulating layer 12 is formed extending from the peripheral portion of the insulating layer 11 to the substrate surface. In this way, the island-like semiconductor region (Si isolation layer) 13 is formed. In this case, the island-like semiconductor region is flush with the substrate surface, and part of the region is isolated electrically from the substrate 10. Therefore, different semiconductor element is formed on each of the Si layer 10 and the Si isolation layer 13.

According to the first embodiment, the insulating layer 12 is formed using oxygen implantation and annealing. Therefore, it is possible to make small the size of the isolation layer as compared with the isolation layer formed using normal field oxide (FOX). This serves to achieve miniaturization of the entire device. In addition, the insulating layers 11 and 12 are selectively formed having a small area. Therefore, an environment ideal for logic elements requiring high performance is given to an arbitrary place on the substrate.

### Second Embodiment

FIG. 5 is a cross-sectional view showing the element structure of a semiconductor device according to a second embodiment of the present invention. Incidentally, the same reference numerals are used to designate the same portions as in FIG. 1, and the detailed explanation is omitted.

According to the second embodiment, in the left-side region of FIG. 5, a re-growth layer 41 is formed on a region surrounded by insulating layers 11 and 12. In the layer re-grown on the region surrounded by these insulating layers 11 and 12, element characteristic enhancement by reduction of crystal defects is expected. In addition, a layer having a lattice constant different from the portion surrounded by these insulating layers 11 and 12 is grown, and thereby, element characteristic enhancement by a change of band structure is expected. For example, a strained SiGe layer is stacked as the re-growth layer 41. In this case, the Ge concentration of the surface side of the SiGe layer 41 is typically 3% or more and 8% or less, preferably 20% or more and 50% or less.

Usually, a SiGe thin film is formed using chemical vapor deposition (CVD) and molecular beam epitaxy (MBE) process. If the SiGe layer 41 is formed using CVD, Si source gas and Ge source gas are introduced onto the Si substrate 10 heated to 550° C. In this way, an SiGe layer having a thickness of 30 nm is deposited on the Si isolation layer 13. For example, dislocation is given to the SiGe layer to relax the strain resulting from the difference in lattice constant between the SiGe layer 41 and the front-end layer. Strain is relaxed so that a strain-relaxed SiGe is given at least to the surface of the SiGe layer 41. In order to obtain the strain-relaxed SiGe, the Ge concentration of the SiGe layer 41 is changed toward the crystal growth direction vertical to the substrate surface. In this way, the lattice constant is changed to the direction vertical to the substrate. In addition, a strained Ge layer having high Ge concentration is formed, and thereafter, an element is formed thereon. The composition is changed, and thereby, it is possible to form desired growth layers corresponding to various elements.

In addition, an SiGe layer realizing strain relaxation by a condensation method with an oxidation process (see T. Tezuka et al., IEDM Tech. Dig., 946 (2001)) is formed on the Si substrate 10 via the insulating layer 11 such as an oxide film. As a result, the SiGe layer has a function as a stressor for applying strain to a strained Si layer (strained Si channel) described later. The strained Si layer has a lattice constant different from the lattice constant d of the front-end surface for growing the layer. More specifically, the strained Si layer has a range of |Δd|<±40%, typically, a range of |Δd|<±2.5%, preferably, a range of |Δd|<±2%.

On the other hand, if Ge is formed as the re-growth layer 41, Ge is formed directly on the Si isolation layer 13. For this reason, the Ge layer is formed as a strained Ge layer resulting from the difference in the lattice constant. As a result, element characteristic enhancement by the strain effect, for example, mobility enhancement is expected. Thereafter, a MOSFET is formed on the strained Ge layer, thereby achieving element characteristic enhancement.

Usually, the gate insulating layer 31 is formed using thermal oxidation. In place of the thermal oxide film, a CVD oxide film or tetraethylorthosilicate (TEOS) film may be used. Low-temperature formable radical oxidation and laser ablation are applicable as the oxidation. In this case, the gate insulating layer 31 is not limited to SiO₂. Recently noticeable metal oxide films such as HfOₓ, HfAlOₓ, HfNOₓ, HfAlNOₓ, ZrO₂, ZrNOₓ, Al₂O₃, SiON, La₂O₃, or high-k materials consisting of a combination of them are applicable. In addition, cerium oxide (CeO2) film may be formed using MBE. In this case, the insulating film is epitaxially grown on the re-growth layer 41, and rare earth oxides such as Ce and Pr, which are typical of cerium oxide film, are applicable in particular.

The gate electrode 32 is formed of polysilicon, and is formed in a manner that the polysilicon is deposited using CVD, and thereafter, patterned to a desired pattern. In the uppermost strained Si layer 41, ion implantation is carried out using the gate electrode 32 as a mask, and thereby, the re-growth layer 41 is formed with a source/drain region.

An interlayer insulating film (not shown) is formed on the re-growth layer 41 formed with the source/drain region (not shown) and the gate electrode 32. The interlayer insulating film is formed with a contact hole for contacting with each of the gate electrode 32 and the source/drain region. Thereafter, interconnects (not shown) are formed to fill the contact hole.

In the formation of the re-growth layer 41 such as SiGe, if a p-type electrode is formed, impurities such as B and Sb may be doped with a desired concentration. Likewise, if an n-type electrode is formed, impurities such as As and P may be doped with a desired concentration.

According to the second embodiment, the re-growth layer 41 formed of strained SiGe and strained Si is used as the channel of the MOSFET. Therefore, it is possible to realize mobility enhancement, and to form logic elements having higher performance. For example, logic elements requiring high performance are formed on the re-growth layer 41 while a DRAM requiring high quality and integration is formed on the substrate 10. In this way, each element is formed on a substrate adaptable to there; therefore, this contributes to reduction of cost and the number of processes.

The re-growth layer 41 having the same composition as the front-end substrate is formed, and thereby, it is possible to obtain a crystal layer higher quality than the front end. Thus, elements such as a DRAM integrated onto the re-growth layer 41 are provided having high reliability. As a result, a high-performance semiconductor device is realized. The desired position of the partial SOI structure is formed with strain elements, which has not been conventionally manufactured. In this way, a high-performance semiconductor element is formed at low cost by reduction of the number of processes. In addition, low power consumption of the manufactured element is achieved.

### Third Embodiment

FIG. 6 is a cross-sectional view showing the element structure of a semiconductor device according to a third embodiment of the present invention. Incidentally, the same reference numerals are used to designate the same portions as FIG. 1, and the details are omitted.

According to the third embodiment, in the right-side element region of FIG. 6, a re-growth layer 51 is formed on the Si substrate 10. In a re-grown crystal layer, element characteristic enhancement by reduction of crystal defects is expected. For example, an advantageous structure is given if elements such as a DRAM having high reliability are formed; therefore, this has a merit when manufacturing embedded elements. On the other hand, if a layer having a lattice constant different from the Si substrate 10 is grown, element characteristic enhancement with a change of band structure is expected. The foregoing Ge layer may be used as the re-growth layer 51, and the same effect as above is obtained.

### Fourth Embodiment

FIG. 7 is a cross-sectional view showing the element structure of a semiconductor device according to a fourth embodiment of the present invention. Incidentally, the same reference numerals are used to designate the same portions as FIG. 1, and the details are omitted.

According to the fourth embodiment, in the left-side region of FIG. 7, a re-growth layer 41 is formed on a region surrounded by insulating layers 11 and 12. In the layer re-grown on the region surrounded by these insulating layers 11 and 12, element characteristic enhancement by reduction of crystal defects is expected. In addition, a layer having a lattice constant different from the portion surrounded by the insulating layers 11 and 12 is grown, and thereby, element characteristic enhancement by a change of band structure is expected.

On the other hand, in the right-side element region of FIG. 7, a re-growth layer 51 is formed on the Si substrate 10. In a re-grown crystal layer, element characteristic enhancement by reduction of crystal defects is expected. For example, an advantageous structure is given if elements such as a DRAM having high reliability are formed; therefore, this has a merit when manufacturing embedded elements. On the other hand, if a layer having a lattice constant different from the Si substrate 10 is grown, element characteristic enhancement with a change of band structure is expected. The foregoing Ge layer may be used as the re-growth layer 51, and the same effect as above is obtained.

### Fifth Embodiment

FIG. 8 is a cross-sectional view showing the element structure of a semiconductor device according to a fifth embodiment of the present invention. Incidentally, the same reference numerals are used to designate the same portions as FIG. 1, and the details are omitted.

According to the fifth embodiment, in the left-side region of FIG. 8, a strain-relaxed SiGe layer is formed as a re-growth layer 71 on a region surrounded by insulating layers 11 and 12. A strained Si layer 72 is further formed on the strain-relaxed SiGe layer. When the structure described above is given, it is possible to combine transistors achieving reduction of parasitic capacitance by the SOI structure and using the strained Si layer as a channel. In this way, elements having high speed and low power consumption are formed. In this case, preferably, the strained Si layer 72 has a lattice constant different from the lattice constant d of the front-end surface for growing the layer 72, that is, a range of |Δd|<±2%.

On the other hand, in the right-side element region of FIG. 8, a re-growth layer 51 is formed on the Si substrate 10. In a re-grown crystal layer, element characteristic enhancement by reduction of crystal defects is expected. For example, an advantageous structure is given if elements such as a DRAM having high reliability are formed; therefore, this has a merit when manufacturing embedded elements. Therefore, high-performance logic elements and memory elements are readily integrated on one chip as compared with the conventional case.

### Sixth Embodiment

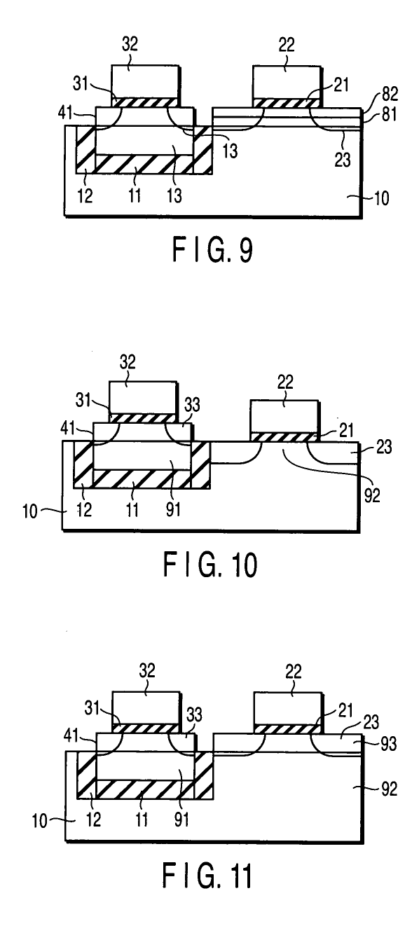

FIG. 9 is a cross-sectional view showing the element structure of a semiconductor device according to a sixth embodiment of the present invention. Incidentally, the same reference numerals are used to designate the same portions as FIG. 1, and the details are omitted.

According to the sixth embodiment, in the left-side region of FIG. 9, a re-growth layer 41 is formed on a region surrounded by insulating layers 11 and 12. In the layer re-grown on the region surrounded by these insulating layers 11 and 12, element characteristic enhancement by reduction of crystal defects is expected. In addition, a layer having a lattice constant different from the portion surrounded by insulating layers 11 and 12 is grown, and thereby, element characteristic enhancement by a change of band structure is expected.

On the other hand, in the right-side element region of FIG. 9, a strain-relaxed SiGe layer 81 and a strained Si layer 82 are formed on the Si substrate 10. When the structure described above is given, element characteristic enhancement by reduction of crystal defects is expected. For example, the structure is applicable to devices such as a DRAM requiring high speed.

### Seventh Embodiment

FIG. 10 is a cross-sectional view showing the element structure of a semiconductor device according to a seventh embodiment of the present invention. Incidentally, the same reference numerals are used to designate the same portions as FIG. 1, and the details are omitted.

According to the structure, a substrate formed with an SiGe layer is prepared on a substrate surface before the process of carrying out ion implantation for forming insulating films 11 and 12 in the Si substrate 10. Thereafter, the same process as the first embodiment is carried out. In heat treatment after ion implantation, Ge diffuses into the substrate in the right side of FIG. 10 formed with no insulating film in the substrate. For this reason, an Si substrate in which Ge slightly exists, that is, a low-concentration Ge layer 92, is formed.

On the other hand, the structural portion is given such that part of the substrate is partially or entirely isolated from the substrate via the isolation layer. Thus, Ge is prevented from diffusing by isolation layers 11 and 12. Therefore, an SiGe layer 91 having the following features is formed. That is, the SiGe layer 91 has a Ge concentration corresponding to the Ge concentration contained in the SiGe layer formed initially on the substrate, and relaxed by heat treatment. As a result, the strained Si layer 41 is formed on the isolated lattice-relaxed SiGe layer, and thereby, the same effect as described in the second and fifth embodiments is obtained. Therefore, a high performance transistor is manufactured. In this case, the strained Si layer 41 and the SiGe layer 91 both have a film thickness thinner than those of the second and fifth embodiments. Thus, the advantages owing to the SOI structure is effectively obtained. In the right-side region having no isolation structure, the Ge concentration is low in the substrate. Therefore, elements are formed via the same process as the Si substrate.

In fact, the SiGe layer is formed on the substrate before ion implantation in a range of Ge concentration x=0 to 100%. Typically, the Ge concentration is 5% to 50%. After the region surrounded by the insulating layers 11 and 12, the Ge concentration of the SiGe layer 91 is determined depending on ion implantation conditions and annealing conditions. The hold of the initial Ge concentration, decrease of Ge concentration by diffusion of Ge to the substrate in heat treatment or increase of Ge concentration by condensation in heat treatment occurs. In contrast, in the right-side substrate portion 92, diffusion of Ge occurs in heat treatment. For this reason, finally, it is usual that the Ge concentration becomes less than half of the initial concentration. There is a possibility that the Ge concentration becomes less than 1%. As seen from FIG. 11, an Si epitaxial layer is further re-grown on the substrate portion 92 to again form a relaxed Si layer 93 containing no Ge.

### MODIFICATION EXAMPLE

The present invention is not limited to the foregoing embodiments. In the preceding embodiments, the Si substrate is used as the semiconductor substrate; in this case, other semiconductor materials may be used without being limited to the Si substrate. That is, a single layer containing at least one of Si, Ge, Ga, As, P, B, N, Sb, C, W, Ti, Ni, Ce, Sr, Pr, In, Al and O or a layer formed of several layers may be used as the Si substrate. More specifically, SiGe, SiGeC, SiC, InGaAs, AlGaAs, GaN, GaAs, InAs and SiN may be used. Moreover, a single layer containing at least one of Si, Ge, Ga, As, P, B, N, Sb, C, W, Ti, Ni, Ce, Sr, Pr, In, Al and O or a layer formed of several layers may be used as the added semiconductor layer.

The first and second insulating layers are not necessarily limited to SiO₂. In this case, another insulating oxide film, insulating nitride film, metal oxide film, magnetic oxide film, crystal layer having insulation property, porous layer and amorphous layer may be used.

The thickness of the strain-relaxed SiGe layer and the strained Si layer formed as the re-growth layer is properly modified in accordance with specifications by changing crystal growth conditions. The memory element is not limited to a DRAM; in this case, the present invention is applicable to an SRAM, flash memory, rewritable memory, e.g., EEPROM, MRAM, FRAM, OUM, etc.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A method of manufacturing a semiconductor device, comprising:
selectively forming a mask having an opening on a semiconductor substrate;
ion-implanting oxygen to a predetermined depth position of the substrate from a surface of the substrate exposed in the opening of the mask;
carrying out annealing with respect to the substrate to oxidize an ion implantation region so that an insulating layer is formed; and
forming a first semiconductor element on a region of the semiconductor substrate on the insulating layer, and forming a second semiconductor element on a region other than the region formed with the insulating layer.

2. The method according to claim 1, wherein selectively forming a mask includes forming silicon oxide film or silicon nitride film having a thickness of 100 to 3000 nm.

3. The method according to claim 1, wherein ion-implanting oxygen includes ion-implanting oxygen under conditions that acceleration voltage is 150 to 250 keV, dose is 1×10¹⁷ to 1×10¹⁸ cm⁻², and substrate temperature is room temperature to 900° C.

4. The method according to claim 1, wherein said ion-implanting oxygen includes implanting ions from an oblique direction to the surface of the substrate.

5. The method according to claim 1, wherein said implanting ions from the oblique direction includes ion-implanting oxygen at an angle θ larger than tan θ=H/L and smaller than 95° with respect to the surface of the substrate when the mask has height H and width L.

6. The method according to claim 1, wherein said forming the insulating layer includes carrying out annealing at a temperature of 900 to 1400° C., in a nitrogen atmosphere in which oxygen partial pressure is 0.1 to 50% for 2 to 20 hours.

7. The method according to claim 1, wherein the semiconductor substrate contains at least one element selected from the group consisting of Si, Ge, Ga, As, P, B, N, Sb, C, W, Ti, Ni, Ce, Sr, Pr, In, Al and O.

8. The method according to claim 1, wherein said forming the first semiconductor element and the second semiconductor element includes forming a logic element as the first semiconductor element and forming a memory element as the second semiconductor element.

9. A semiconductor device comprising:
a semiconductor substrate;
a first insulating film partially formed at a predetermined depth position from a surface of the semiconductor substrate;
a second insulating film formed extending from at least part of the first insulating film to the surface of the semiconductor substrate, a thickness of the second insulating film in a direction parallel to the surface of the second insulating being 40 to 150 nm;
a first semiconductor element formed on a first region of the semiconductor substrate above the first insulating film; and
a second semiconductor element formed on a second region of the semiconductor substrate other than the first region formed with the first insulating film.

10. The device according to claim 9, wherein at least part of the first semiconductor region is surrounded with the first insulating film and the second insulating film, and isolated electrically from the second semiconductor region.

11. The device according to claim 9, wherein the first semiconductor region is surrounded with the first insulating film and the second insulating film formed extending from a peripheral portion of the first insulating film to the surface of the substrate, and isolated electrically from the second semiconductor region.

12. The device according to claim 9, further comprising:
a semiconductor layer formed of a semiconductor material different from the semiconductor substrate formed on the first semiconductor region,
the semiconductor layer having lattice strain.

13. The device according to claim 1, wherein the first semiconductor region is formed of a material different from the semiconductor substrate, and further includes a semiconductor layer formed of the same material as the semiconductor substrate formed on the first semiconductor region.

14. The device according to claim 9, wherein the semiconductor substrate contains at least one element selected from the group consisting of Si, Ge, Ga, As, P, B, N, Sb, C, W, Ti, Ni, Ce, Sr, Pr, In, Al and O.

15. The device according to claim 9, wherein the first semiconductor element is a logic element, and the second semiconductor element is a memory element.

16. A semiconductor device comprising:
a semiconductor substrate;
a first insulating film partially formed at a predetermined depth position from a surface of the semiconductor substrate;
a second insulating film formed extending from at least part of the first insulating film to the surface of the semiconductor substrate;
a first semiconductor element formed on a first region of the semiconductor substrate above the first insulating film; and
a second semiconductor element formed on a second region of the semiconductor substrate other than the first region formed with the first insulating film; and
at least one-layer added semiconductor layer formed on at least one of the first semiconductor region and the second semiconductor region, in which at least part of the first semiconductor element or the second semiconductor element is formed.

17. The device according to claim 16, wherein the added semiconductor layer has a lattice constant different from the surface of the semiconductor substrate, and is applied with strain.

18. The device according to claim 16, wherein the added semiconductor layer has the same lattice constant as the surface of the semiconductor substrate.

19. The device according to claim 16, wherein the semiconductor substrate and the added semiconductor layer contain at least one element selected from the group consisting of Si, Ge, Ga, As, P, B, N, Sb, C, W, Ti, Ni, Ce, Sr, Pr, In, Al and O.

20. The device according to claim 16, wherein the first semiconductor element is a logic element, and the second semiconductor element is a memory element.
